(19) United States
(12) Patent Application Publication
(10) Pub. No.: US 2025/0386637 A1
(43) Pub. Date: Dec. 18, 2025

(54) DISPLAY DEVICE COMPRISING CONTACT STRUCTURE, METHOD OF MANUFACTURING CONTACT STRUCTURE, AND ELECTRONIC DEVICE COMPRISING DISPLAY DEVICE

(71) Applicant: SAMSUNG DISPLAY CO., LTD., Yongin-si (KR)

(72) Inventors: Han Bit KIM, Yongin-si (KR); Mee Jae KANG, Yongin-si (KR); Ji Yeong SHIN, Yongin-si (KR); Do Kyeong LEE, Yongin-si (KR); Ki Seok CHOI, Yongin-si (KR); Sang Gun CHOI, Yongin-si (KR); Tae Hyun HONG, Yongin-si (KR)

(21) Appl. No.: 18/985,657

(22) Filed: Dec. 18, 2024

(30) Foreign Application Priority Data
Jun. 14, 2024 (KR) 10-2024-0077619

(51) Int. Cl. H10H 29/49; H10D 86/40; H10D 86/60; H10H 29/01; H10H 29/32; H10H 29/41

(52) U.S. Cl. CPC H10H 29/49; H10D 86/423; H10D 86/60; H10H 29/012; H10H 29/32; H10H 29/41

(57) ABSTRACT

A display device includes a pixel circuit layer including a contact structure having a first conductive layer, a first bridge layer electrically connected to the first conductive layer, a second bridge layer electrically connected to the first bridge layer, and a second conductive layer electrically connected to the second bridge layer. A light-emitting element is disposed on the pixel circuit layer. The first conductive layer and the first bridge layer are connected to each other in a first contact area, and the second conductive layer and the second bridge layer are connected to each other in a second contact area. The first contact area and the second contact area overlap each other, in a plan view.

### CROSS-REFERENCE TO RELATED PATENT APPLICATION

This application claims priority under 35 U.S.C. § 119 to Korean Patent Application No. 10-2024-0077619, filed on Jun. 14, 2024 in the Korean Intellectual Property Office, the disclosure of which is incorporated by reference in its entirety herein.

### 1. TECHNICAL FIELD

The present disclosure relates to a display device including a contact structure, a method of manufacturing the contact structure, and an electronic device comprising the display device.

### 2. DISCUSSION OF RELATED ART

There has been increased research and development concerning an information display along with the advancement of the information society. A display device may include two or more layers. The two or more layers may be electrically connected to each other by a contact structure. However, as the demand for a display device with high-resolution characteristics increases, there has been an increase in closely arranged configurations for the display device to form the display device in a relatively narrow area.

### SUMMARY

One aspect of the present disclosure is to provide a display device including a contact structure, a method of manufacturing the contact structure, and an electronic device comprising the display device, with high-resolution characteristics and excellent display quality.

One aspect of the present disclosure is to provide a display device including a contact structure, a method of manufacturing the contact structure, and an electronic device comprising the display device, in which the contact structure may be closely arranged in a relatively narrow area.

According to an embodiment of the present disclosure, a display device includes a pixel circuit layer including a contact structure having a first conductive layer, a first bridge layer electrically connected to the first conductive layer, a second bridge layer electrically connected to the first bridge layer, and a second conductive layer electrically connected to the second bridge layer. A light-emitting element is disposed on the pixel circuit layer. The first conductive layer and the first bridge layer are connected to each other in a first contact area, and the second conductive layer and the second bridge layer are connected to each other in a second contact area. The first contact area and the second contact area overlap each other, in a plan view.

According to an embodiment, the pixel circuit layer may include a pixel circuit electrically connected to the light-emitting element and wiring electrically connected to the pixel circuit. The contact structure may comprise an electrical path in the pixel circuit or the wiring. The first conductive layer may include one of a metal material and a semiconductor material. The second conductive layer may include a metallic material.

According to an embodiment, the contact structure may further include a first insulation layer disposed on the first conductive layer, and including a lower contact hole exposing the first conductive layer. An inorganic insulation layer is disposed on the first bridge layer, and including an intermediate contact hole exposing the first bridge layer. A second insulation layer is disposed on the inorganic insulation layer and the second bridge layer, and includes an upper contact hole exposing the second bridge layer.

According to an embodiment, the lower contact hole, the intermediate contact hole, and the upper contact hole may overlap each other, in the plan view.

According to an embodiment, a portion of the inorganic insulation layer may be disposed within the lower contact hole, and the contact structure may further include a buffer insulation layer disposed in the lower contact hole and covering the portion of the inorganic insulation layer within the lower contact hole.

According to an embodiment, the buffer insulation layer and the inorganic insulation layer may include different materials from each other.

According to an embodiment, the buffer insulation layer may have a flat upper surface, and may not cover a portion of the first bridge layer exposed by the intermediate contact hole.

According to an embodiment, the inorganic insulation layer may face the intermediate contact hole and include an end part covered by the second bridge layer. The second bridge layer may be disposed in an area greater than or equal to the lower contact hole and entirely covers the lower contact hole, in the plan view.

According to an embodiment, the intermediate contact hole may have a greater diameter than the lower contact hole.

According to an embodiment, the intermediate contact hole may have a greater diameter than the upper contact hole.

According to an embodiment, the lower contact hole may have a greater diameter than the upper contact hole.

According to an embodiment, the pixel circuit layer may include a base layer, a first transistor disposed on the base layer and including a first active layer, and a second transistor disposed on the base layer and including a second active layer. The second transistor may be spaced further away from the base layer than the first transistor. The first active layer and the second active layer may include different semiconductor materials from each other.

According to an embodiment, the first active layer may include a polysilicon semiconductor material. The second active layer may include an oxide semiconductor material.

According to an embodiment of the present disclosure, a display device may include a pixel circuit layer including a contact structure. A light-emitting element is disposed on the pixel circuit layer. The contact structure may include a first conductive layer. An insulation layer is disposed on the first conductive layer, and including a lower contact hole exposing a portion of the first conductive layer. A bridge layer is electrically connected to the portion of the first conductive layer exposed by the lower contact hole. An inorganic insulation layer exposing a portion of the bridge layer. A portion of the inorganic insulation layer is disposed within the lower contact hole. A buffer insulation layer is disposed in the lower contact hole. The inorganic insulation layer and the buffer insulation layer may include different materials from each other.

According to an embodiment of the present disclosure, a method of manufacturing a contact structure may include forming a first conductive layer on a contact base. A first insulation layer is formed on the first conductive layer and the first insulation layer is patterned. A first bridge layer is formed that is electrically connected to the first conductive layer. An inorganic insulation layer is formed on the first bridge layer. A buffer insulation layer is formed on the inorganic insulation layer. A second bridge layer is formed on the first bridge layer, the inorganic insulation layer and the buffer insulation layer. The second bridge layer is electrically connected to the first bridge layer. A second insulation layer is formed on the second bridge layer and the second insulation layer is patterned. A second conductive layer is formed on the second insulation layer. The second conductive layer is electrically connected to the second bridge layer.

According to an embodiment, the forming of the buffer insulation layer may include forming a base buffer insulation layer on the inorganic insulation layer; and removing a portion of the base buffer insulation layer. The base buffer insulation layer and the inorganic insulation layer may include different materials from each other.

According to an embodiment, the removing of the portion of the base buffer insulation layer may include removing the base buffer insulation layer until an upper surface of the inorganic insulation layer is exposed. The removing of the portion of the base buffer insulation layer is performed by a chemical mechanical polishing (CMP) process.

According to an embodiment, the manufacturing method may further include, after the forming of the buffer insulation layer, exposing the first bridge layer by removing at least a portion of the inorganic insulation layer. The patterning of the first insulation layer may include forming a lower contact hole exposing the first conductive layer. The exposing of the first bridge layer may include forming an intermediate contact hole exposing the first bridge layer. The patterning of the second insulation layer may include forming an upper contact hole exposing the second bridge layer.

According to an embodiment, a portion of the inorganic insulation layer and the buffer insulation layer may be disposed in the lower contact hole.

According to an embodiment, the forming of the second bridge layer may include covering the first bridge layer and the portion of the inorganic insulation layer and the buffer insulation layer in the lower contact hole with the second bridge layer.

According to an embodiment of the present disclosure, a display device includes a pixel circuit layer comprising a contact structure. A light-emitting element is disposed on the pixel circuit layer. The contact structure includes a first conductive layer disposed on a contact base. An insulation layer is disposed on the first conductive layer. The insulation layer includes a lower contact hole exposing a portion of the first conductive layer. A first bridge layer is disposed on the insulation layer. The first bridge layer includes a first portion disposed above the insulation layer and a second portion extending within the lower contact hole and directly contacting the portion of the first conductive layer exposed by the lower contact hole in a first contact area. An inorganic insulation layer is disposed on the first and second portions of the first bridge layer. The inorganic insulation layer includes an intermediate contact hole partially exposing the first portion of the first bridge layer. The first portion of the first bridge layer exposed by the intermediate contact hole has a substantially flat upper surface. A buffer insulation layer is disposed on the inorganic insulation layer in the lower contact hole. A second bridge layer is disposed in the intermediate contact hole and directly contacts the substantially flat upper surface of the first portion of the first bridge layer exposed by the intermediate contact hole in an intermediate contact area. A second conductive layer is electrically connected to the second bridge layer in a second contact area.

According to an embodiment of the present disclosure, an electronic device, comprising: a processor configured to provide input image data; a display device configured to display an image based on the input image data, the display device including sub-pixel areas; and a power supply configured to supply power to the display device. The display device comprises: a pixel circuit layer comprising a contact structure that includes a first conductive layer, a first bridge layer electrically connected to the first conductive layer, a second bridge layer electrically connected to the first bridge layer, and a second conductive layer electrically connected to the second bridge layer; and a light-emitting element disposed on the pixel circuit layer. The first conductive layer and the first bridge layer are directly connected to each other in a first contact area, and the second conductive layer and the second bridge layer are directly connected to each other in a second contact area. The first contact area and the second contact area overlap each other, in a plan view.

According to an embodiment of the present disclosure, a display device including a contact structure, a method of manufacturing the contact structure, and an electronic device comprising the display device, achieving high-resolution characteristics and excellent display quality, may be provided.

According to an embodiment of the present disclosure, a display device including a contact structure, a method of manufacturing the contact structure, and an electronic device comprising the display device, in which the contact structure may be closely arranged in a relatively narrow area, may be provided.

### BRIEF DESCRIPTION OF THE DRAWINGS

FIG. 1 is a plan view illustrating a display device according to an embodiment of the present disclosure.

FIGS. 2 and 3 are schematic cross-sectional diagrams illustrating a display device according to embodiments of the present disclosure.

FIG. 4 is a block diagram illustrating a contact structure according to an embodiment of the present disclosure.

FIG. 5 is a schematic cross-sectional diagram illustrating a contact structure according to an embodiment of the present disclosure.

FIG. 6 is a schematic cross-sectional diagram illustrating a pixel circuit layer according to an embodiment of the present disclosure.

FIG. 7 is a schematic enlarged view of an area EA1 of FIG. 6 according to an embodiment of the present disclosure.

FIG. 8 is a schematic enlarged view of an area EA2 of FIG. 6 according to an embodiment of the present disclosure.

FIGS. 9 to 16 are schematic cross-sectional diagrams of process stages illustrating a method of manufacturing a contact structure according to embodiments of the present disclosure.

FIG. 17 is a schematic block diagram illustrating an electronic device including a display device in accordance with an embodiment.

FIG. 18 is a schematic diagram illustrating an example where the electronic device of FIG. 17 is implemented as a smartphone.

FIG. 19 is a schematic diagram illustrating an example where the electronic device of FIG. 17 is implemented as a tablet computer.

### DETAILED DESCRIPTION OF EMBODIMENTS

The present disclosure may make various modifications and have various forms, and non-limiting embodiments shall be illustrated in the drawings and described in detail. However, it should be appreciated that the described embodiments are not intended to limit the present disclosure to particular modes of practice. Instead, embodiments of the present disclosure encompass all changes, equivalents and replacements falling within the spirit and technical scope of the present disclosure.

Terms such as first and second may be used to describe various components, but the components should not be limited by the above terms. The terms are only used to distinguish one component from another. For example, a first component may be referred to as a second component, and similarly, a second component may be referred to as a first component without departing from the scope of the present disclosure. An expression used in the singular encompasses the expression of the plural, unless the context clearly indicates otherwise.

In the present disclosure, it is to be understood that terms such as “comprising”, “including” or “having” are intended to indicate existence of features, numbers, steps, operations, components, parts, or combinations thereof disclosed in the specification, and are not intended to preclude the possibility that one or more other features, numbers, steps, operations, components, parts, or combinations thereof may exist or may be added. In addition, if a part such as a layer, a film, a region, or a plate is disposed “on” another part, this indicates not only a case where the part is disposed “directly on” the other part but also a case where a further part is interposed therebetween. In contrast, if a part such as a layer, a film, a region, or a plate is disposed “directly on” another part, no intervening elements may be interposed therebetween. Also, if a part such as a layer, a film, a region, or a plate is formed on another part, the formed direction is not limited to an upper direction but includes a lateral or lower direction. To the contrary, if a part such as a layer, a film, a region, or a plate is disposed “below” another part, this indicates not only a case where the part is disposed “directly below” the other part but also a case where a further part is interposed therebetween.

The present disclosure relates to a display device including a contact structure, a method of manufacturing the contact structure, and an electronic device comprising the display device. Hereafter, the display device including the contact structure, the method of manufacturing the contact structure, and an electronic device comprising the display device are described according to non-limiting embodiments with reference to the accompanying drawings.

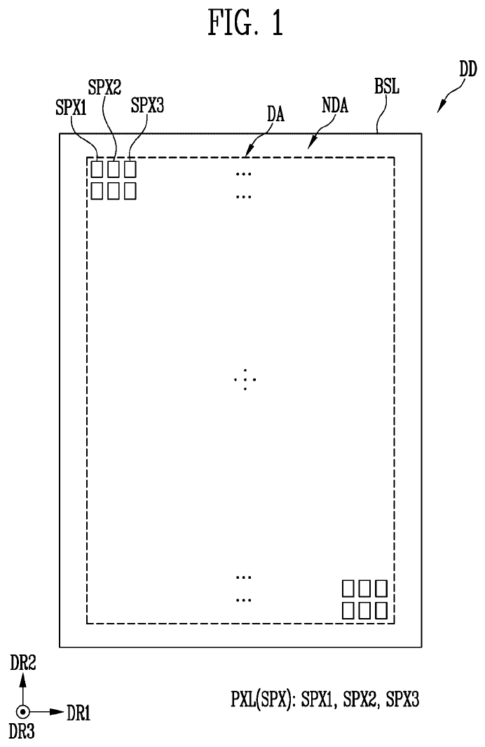

FIG. 1 is a schematic plan view illustrating a display device according to an embodiment.

Referring to FIG. 1, a display device DD may include a base layer BSL and a pixel PXL disposed on the base layer BSL. In an embodiment, the display device DD may further include a driving circuit (e.g., a scanning driver and a data driver) for driving the pixel PXL, wiring, and pads.

In an embodiment, the display device DD (e.g., the base layer BSL) may include a display area DA and a non-display area NDA. The non-display area NDA may indicate an area other than the display area DA. The non-display area NDA may surround at least a portion of the display area DA (e.g., in the first and/or second directions DR1, DR2).

The base layer BSL may form a base surface of the display device DD. According to an embodiment, the base layer BSL may be a lower substrate for arranging layers which form the display device DD. The base layer BSL may be a rigid or flexible substrate or film. For example, in an embodiment the base layer BSL may include a glass material. Alternatively, the base layer BSL may include a silicone material. Alternatively, the base layer BSL may include polyimide. However, embodiments of the present disclosure are not necessarily limited thereto.

A plane defined in this specification is a direction extending in a first direction DR1 and a second direction DR2, and may be defined based on a plane on which the base layer BSL is disposed. According to an embodiment, a third direction DR3 may be a thickness direction of the base layer BSL, and the third direction DR3 may be a light exit direction of the display device DD.

The display area DA may indicate an area where the pixel PXL is disposed. The non-display area NDA may indicate an area where no pixels PXL are disposed. In an embodiment, a drive circuit, wiring, and pads connected to the pixel PXL of the display area DA may be disposed in the non-display area NDA.

The pixel PXL may include a plurality of sub-pixels SPX. According to an embodiment, the pixel PXL, such as the sub-pixels SPX, may be arranged according to a stripe or pentile (PENTILE™) array structure. However, embodiments of the present disclosure are not necessarily limited thereto, and the pixel PXL may have various other arrangements.

According to an embodiment, the pixel PXL (e.g., the sub-pixels SPX) may include a first sub-pixel SPX1, a second sub-pixel SPX2, and a third sub-pixel SPX3. The first sub-pixel SPX1, the second sub-pixel SPX2, and the third sub-pixel SPX3 each may be a sub-pixel. At least one first sub-pixel SPX1, second sub-pixel SPX2, and third sub-pixel SPX3 may form a single pixel unit for emitting light of various colors.

The first sub-pixel SPX1, the second sub-pixel SPX2, and the third sub-pixel SPX3 each may emit light of a single color.

For example, in an embodiment the first sub-pixel SPX1 may be a red pixel which emits red light (e.g., a first color), the second sub-pixel SPX2 may be a green pixel which emits green light (e.g., a second color), and the third sub-pixel SPX3 may be a blue pixel which emits blue light (e.g., a third color). The red pixel may provide light in a wavelength range of 600 nm through 750 nm. The green pixel may provide light in a wavelength range of 480 nm through 560 nm. The blue pixel may provide light in a wavelength range of 370 nm through 460 nm.

According to an embodiment, the number of the second sub-pixels SPX2 may be greater than the number of the first sub-pixels SPX1 and the number of the third sub-pixels SPX3. However, embodiments of the present disclosure are not necessarily limited thereto and the color, the type, and the number of the first sub-pixels SPX1, the second sub-pixels SPX2, and the third sub-pixels SPX3 which form each pixel unit may vary.

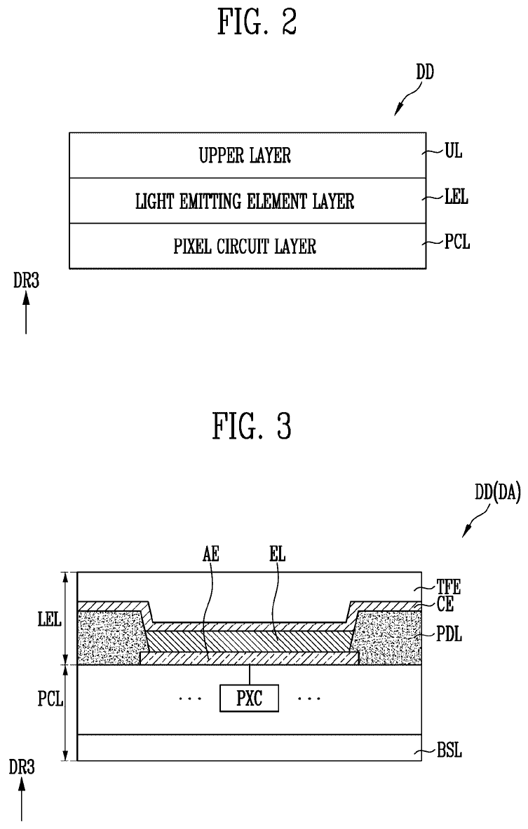

FIGS. 2-3 are schematic cross-sectional diagrams illustrating a display device according to embodiments of the present disclosure. FIG. 3 shows a portion of the display device DD in the display area DA.

Referring to FIG. 2 and FIG. 3, in an embodiment the display device DD may include a pixel circuit layer PCL and a light-emitting element layer LEL. The display device DD may further include an upper layer UL. The pixel circuit layer PCL, a light-emitting element layer LEL and the upper layer UL may be consecutively arranged in the third direction DR3.

In an embodiment, the pixel circuit layer PCL may include a base layer BSL. The pixel circuit layer PCL may be a layer including a pixel circuit PXC. The pixel circuit layer PCL may be a backplane layer. The pixel circuit PXC may be formed on the base layer BSL, and may be configured to drive a light emitting device LD. In an embodiment, the pixel circuit layer PCL may include conductive layers and insulation layers, and the conductive layers may form the pixel circuit PXC. The pixel circuit PXC may include circuit elements. The circuit elements may include drive transistors, and may include additional transistors and capacitors.

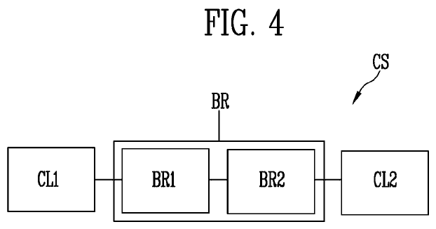

According to an embodiment, the pixel circuit layer PCL may further include a contact structure CS (see FIG. 4). The contact structure CS may form a portion of the pixel circuit PXC, and may also form at least a portion of other wiring electrically connected to the pixel circuit PXC. Details of the contact structure CS shall be described below with reference to the drawings after FIG. 4.

The light-emitting element layer LEL may be disposed on the pixel circuit layer PCL (e.g., disposed directly thereon in the third direction DR3). The light-emitting element layer LEL may include the light emitting device LD. The light-emitting element layer LEL may further include a pixel definition layer PDL and an encapsulation layer TFE.

The light emitting device LD may be electrically connected to the pixel circuit PXC. According to an embodiment, the light emitting device LD may include an organic light emitting diode (OLED) including an organic material. Alternatively, according to an embodiment, the light emitting device LD may include an inorganic LED including an inorganic material. However, embodiments of the present disclosure are not necessarily limited thereto. For convenience of explanation in this specification, it is explained based on an embodiment in which the light emitting device LD is an OLED.

In an embodiment, the light emitting device LD may include anode electrodes AE, an emission structure EL, and a cathode electrode CE. According to an embodiment, the emission structure EL may be disposed in an area defined by the pixel definition layer PDL. The pixel definition layer PDL may be adjacent to a periphery of the emission structure EL. One surface (e.g., a first surface in the third direction DR3) of the emission structure EL may be electrically connected to the anode electrodes AE, and the other surface (e.g., a second surface opposite to the first surface in the third direction DR3) of the emission structure EL may be electrically connected to the cathode electrode CE. The anode electrodes AE and the cathode electrode CE may include various conductive materials.

The emission structure EL may include a plurality of layers. For example, in an embodiment the emission structure EL may include a plurality of emission structures including a hole transporter, a light emitting layer (or a light generation layer), and an electron transporter. In an embodiment, the layers forming the emission structure each may include one organic material, and may further include a metal-containing compound or an inorganic material such as a quantum dot.

The hole transporter may include a multi-layer structure having a plurality of layers including different materials respectively. For example, in an embodiment the hole transporter may include a hole injection layer and a hole transport layer, and may further include a light emission auxiliary layer and an electron blocking layer.

The light emitting layer may include a material for emitting light of one color. The light emitting layer may include a host and a dopant. The host of the light emitting layer is a light emitting material for capturing carriers (e.g., electrons and holes) for the light generation, and may induce efficient exciton production. In an embodiment, the dopant may include a phosphor dopant or a fluorescent dopant. However, embodiments of the present disclosure are not necessarily limited thereto and the composition of the dopant may vary. According to an embodiment, the dopant may include one organic material or a metal complex.

The electronic transporter may include a multi-layer structure with a plurality of layers including different materials respectively. In an embodiment, the electron transporter may include an electron injection layer and an electron transport layer, and may further include an electron buffer layer, a hole blocking layer, etc.

The pixel definition layer PDL may be disposed on the pixel circuit layer PCL (e.g., disposed directly thereon in the third direction DR3), to define a position for arranging the emission structure EL. For example, the pixel definition layer PDL may directly contact a portion of the anode electrode AE (e.g., lateral edges of the anode electrode AE) and have an opening exposing a portion (e.g. a central portion) of the anode electrode AE to define an emission area. The pixel definition layer PDL may include an organic material or an inorganic material. For example, in an embodiment the pixel definition layer PDL may include a plurality of layers each including an inorganic material. However, embodiments of the present disclosure are not necessarily limited thereto.

The encapsulation layer TFE may be disposed on the light emitting device LD (e.g., the cathode electrode CE). The encapsulation layer TFE may cancel a step caused by the light emitting device LD and the pixel definition layer PDL. The encapsulation layer TFE may include a plurality of insulation layers for covering the light emitting device LD. For example, in an embodiment, the encapsulation layer TFE may include an inorganic layer and an organic layer. For example, the encapsulation layer TFE may have a structure in which a first inorganic layer/an organic layer/a second inorganic layer are sequentially arranged (e.g., in the third direction DR3). However, embodiments of the present disclosure are not necessarily limited thereto. According to an embodiment, the encapsulation layer TFE may be a thin-film encapsulation film.

The upper layer UL may be disposed on the light-emitting element layer LEL (e.g., disposed directly thereon in the third direction DR3). In an embodiment, the upper layer UL may include various light-transmitting layer(s) such as a cover window. According to an embodiment, the upper layer UL may include a color filter, may include a lens array layer, and may include a polarization layer. However, embodiments of the present disclosure are not necessarily limited thereto.

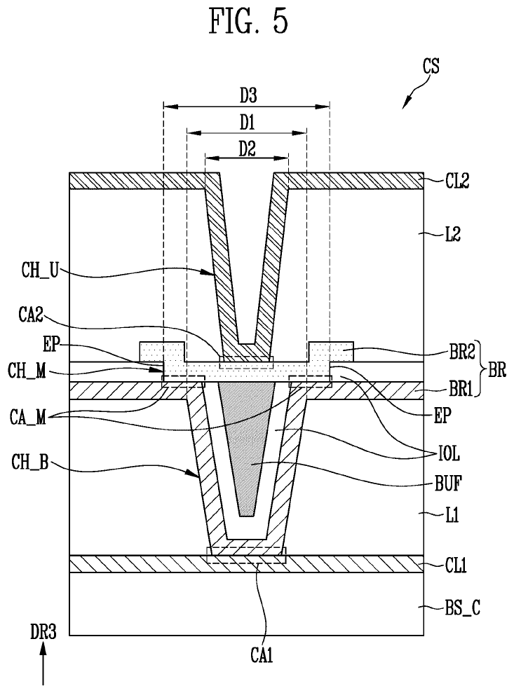

Referring to FIGS. 4 and 5, a contact structure CS according to embodiments of the present disclosure are described.

FIG. 4 is a block diagram illustrating a contact structure CS according to an embodiment. FIG. 5 is a schematic cross-sectional diagram illustrating a contact structure CS according to an embodiment.

The contact structure CS may be included in the pixel circuit layer PCL. For example, in an embodiment contact structure CS may be disposed (e.g., formed) on the base layer BSL, and the contact structure CS may be disposed between the light emitting device LD and the base layer BSL (e.g., in the third direction DR3).

The contact structure CS may be conductive structures formed in the pixel circuit layer PCL and a structure for electrically connecting them.

The contact structure CS may form an electrical path formed in the pixel circuit layer PCL. For example, in an embodiment the contact structure CS may be a portion which forms at least a part of the pixel circuit PXC. The contact structure CS may be a portion which forms at least a portion of wiring electrically connected to the pixel circuit PXC (e.g., gate wiring, data wiring, power supply wiring, etc.).

In an embodiment, the contact structure CS may include a contact base BS_C and a first conductive layer CL1 and a second conductive layer CL2 disposed on the contact base BS_C, and may include layers which form a structure for electrically interconnecting the first conductive layer CL1 and the second conductive layer CL2 to each other. For example, in an embodiment the contact structure CS may electrically interconnect the first conductive layer CL1 and the second conductive layer CL2 to each other and may include a bridge layer BR including a first bridge layer BR1 and a second bridge layer BR2. In an embodiment, the contact structure CS may include a first insulation layer L1, an inorganic insulation layer IOL, a buffer insulation layer BUF, and a second insulation layer L2.

The contact base BS_C may form a base of the contact structure CS. The contact base BS_C may form a base (e.g., a base member) on which the first conductive layer CL1 is disposed. The contact base BS_C may be one of various layers along the layers which form the contact structure CS. For example, the contact base BS_C may be a layer disposed below the first conductive layer CL1 (e.g., in a direction opposite to the third direction DR3). According to an embodiment, the contact base BS_C may be another insulating structural layer disposed below the first conductive layer CL1.

The first conductive layer CL1 may be disposed on the contact base BS_C (e.g., disposed directly thereon in the third direction DR3).

The first conductive layer CL1 may include various conductive materials. For example, the first conductive layer CL1 may include a metallic material. For example, in an embodiment the first conductive layer CL1 may include one or more of gold (Au), silver (Ag), tantalum (Ta), aluminum (Al), molybdenum (Mo), chromium (Cr), titanium (Ti), nickel (Ni), neodymium (Nd), copper (Cu), and platinum (Pt). According to an embodiment, the first conductive layer CL1 may include a semiconductor material (e.g., an oxide semiconductor or a polysilicon semiconductor, etc.). However, embodiments of the present disclosure are not necessarily limited thereto.

The first insulation layer L1 may be disposed on the first conductive layer CL1 (e.g., disposed directly thereon in the third direction DR3).

In an embodiment, the first insulation layer L1 may include a lower contact hole CH_B. The lower contact hole CH_B may expose a portion of the first conductive layer CL1.

The first insulation layer L1 may include various insulation materials. For example, the first insulation layer L1 may include an inorganic material. According to an embodiment, the first insulation layer L1 may include one or more compounds selected from silicon nitride (SiNx), silicon oxide (SiOx), silicon oxide (SiOxNy), and aluminum oxide (AlxOy). However, embodiments of the present disclosure are not necessarily limited thereto. According to an embodiment, the first insulation layer L1 may include an organic material.

The first insulation layer L1 may have a single-layer structure, or may include a plurality of layers, according to an embodiment.

A first bridge layer BR1 may be disposed on (e.g., disposed directly thereon) the first insulation layer L1. At least a portion of the first bridge layer BR1 may be disposed in the lower contact hole CH_B.

The first bridge layer BR1 may directly contact and be electrically connected to the portion of the first conductive layer CL1 exposed by the lower contact hole CH_B.

The first bridge layer BR1 and the first conductive layer CL1 may be interconnected in a first contact area CA1. For example, the first bridge layer BR1 and the first conductive layer CL1 may directly contact each other in the first contact area CA1.

The first bridge layer BR1 may include various conductive materials. For example, in an embodiment the first bridge layer BR1 may include one or more compounds selected from gold (Au), silver (Ag), tantalum (Ta), aluminum (Al), molybdenum (Mo), chromium (Cr), titanium (Ti), nickel (Ni), neodymium (Nd), copper (Cu), and platinum (Pt). However, embodiments of the present disclosure are not necessarily limited thereto.

An inorganic insulation layer IOL may be disposed on the first bridge layer BR1 (e.g., disposed directly thereon in the third direction DR3). In an embodiment, a portion of the inorganic insulation layer IOL may be disposed in the lower contact hole CH_B. In an embodiment, another portion of the inorganic insulation layer IOL may be disposed on an upper surface, which is substantially flat, of the first bridge layer BR1.

The inorganic insulation layer IOL may cover the first bridge layer BR1, and expose at least a portion of the first bridge layer BR1.

The inorganic insulation layer IOL may include an intermediate contact hole CH_M defined therein. The intermediate contact hole CH_M may expose the first bridge layer BR1, and expose the buffer insulation layer BUF.

The inorganic insulation layer IOL may include various insulation materials. For example, the inorganic insulation layer IOL may include an inorganic material. According to an embodiment, the inorganic insulation layer IOL may include one or more compounds selected from silicon nitride (SiNx), silicon oxide (SiOx), silicon oxide (SiOxNy), and aluminum oxide (AlxOy). However, embodiments of the present disclosure are not necessarily limited thereto.

The buffer insulation layer BUF may be disposed on (e.g., disposed directly thereon) the inorganic insulation layer IOL. The buffer insulation layer BUF may be disposed in the lower contact hole CH_B. The buffer insulation layer BUF may not be disposed on the upper surface, which is substantially flat, of the inorganic insulation layer IOL.

In an embodiment, the buffer insulation layer BUF may fill the lower contact hole CH_B together with the inorganic insulation layer IOL and the first bridge layer BR1. The upper surface of the buffer insulation layer BUF may be substantially flat.

The buffer insulation layer BUF may not cover the portion of the first bridge layer BR1 exposed by the inorganic insulation layer IOL.

The buffer insulation layer BUF may include various insulation materials. For example, the buffer insulation layer BUF may include an inorganic material. According to an embodiment, the buffer insulation layer BUF may include one or more compounds selected from silicon nitride (SiNx), silicon oxide (SiOx), silicon oxide (SiOxNy), and aluminum oxide (AlxOy). However, embodiments of the present disclosure are not necessarily limited thereto.

According to an embodiment, the buffer insulation layer BUF may be a buffer structural layer for performing a flattening process, such as a chemical mechanical polishing (CMP) process, etc. For example, in an embodiment after the inorganic insulation layer IOL is formed, the buffer structural layer may be disposed thereon, and the CMP process may be performed. According to an embodiment, the buffer insulation layer BUF and the inorganic insulation layer IOL may include different materials from each other, to achieve a stopper function for the flattening process, and thus, the buffer insulation layer BUF and the inorganic insulation layer IOL may have different etch rates. For example, the buffer insulation layer BUF may include silicon oxide (SiOx) and the inorganic insulation layer IOL may include silicon nitride (SiNx). Alternatively, the buffer insulation layer BUF may include silicon nitride (SiNx) and the inorganic insulation layer IOL may include silicon oxide (SiOx). Hence, the flattening process may be performed until the area where the inorganic insulation layer IOL is formed is reached, and the flattening process may be conducted within an appropriate range.

The second bridge layer BR2 may be disposed on (e.g., disposed directly thereon) the buffer insulation layer BUF, the first bridge layer BR1, and the inorganic insulation layer IOL. The second bridge layer BR2 may not be disposed in the lower contact hole CH_B.

The second bridge layer BR2 may be electrically connected to a portion of the first bridge layer BR1 exposed by the inorganic insulation layer IOL.

The second bridge layer BR2 and the first bridge layer BR1 may be connected to each other in the intermediate contact area CA_M. For example, the second bridge layer BR2 and the first bridge layer BR1 may directly contact each other in the intermediate contact area CA_M.

In an embodiment, the intermediate contact area CA_M may not overlap with the buffer insulation layer BUF, in a plan view. In an embodiment, the intermediate contact area CA_M may not overlap with the lower contact hole CH_B, in a plan view. For example, in an embodiment the intermediate contact area CA_M and the first contact area CA1 may not overlap each other (e.g., in the third direction DR3). The intermediate contact area CA_M may be formed on the upper surface of the first bridge layer BR1, which is substantially flat to provide increased contact between the first bridge layer BR1 and the second bridge layer BR2 in the intermediate contact area CA_M.

In an embodiment, the second bridge layer BR2 may entirely cover an end part EP of the inorganic insulation layer IOL. The end part EP may face the intermediate contact hole CH_M, and the end part EP may define the intermediate contact hole CH_M. Hence, the second bridge layer BR2 may closely cover the portion of the first bridge layer BR1 exposed by the inorganic insulation layer IOL.

The second bridge layer BR2 may cover the buffer insulation layer BUF.

The second bridge layer BR2 may be disposed in the area which is greater than or equal to the lower contact hole CH_B, in a plan view. For example, the second bridge layer BR2, in a plan view, may entirely cover the lower contact hole CH_B and the buffer insulation layer BUF.

The second bridge layer BR2 may include various conductive materials. For example, in an embodiment the second bridge layer BR2 may include one or more compounds selected from gold (Au), silver (Ag), tantalum (Ta), aluminum (Al), molybdenum (Mo), chromium (Cr), titanium (Ti), nickel (Ni), neodymium (Nd), copper (Cu), and platinum (Pt). However, embodiments of the present disclosure are not necessarily limited thereto.

The second insulation layer L2 may be disposed on (e.g., disposed directly thereon) the inorganic insulation layer IOL and the second bridge layer BR2.

In an embodiment, the second insulation layer L2 may include an upper contact hole CH_U. The upper contact hole CH_U may expose a portion of the second bridge layer BR2.

According to an embodiment, the upper contact hole CH_U may overlap with the lower contact hole CH_B, in a plan view.

The second insulation layer L2 may include various insulation materials. For example, the second insulation layer L2 may include an inorganic material. According to an embodiment, the second insulation layer L2 may include one or more compounds selected from silicon nitride (SiNx), silicon oxide (SiOx), silicon oxide (SiOxNy), and aluminum oxide (AlxOy). However, embodiments of the present disclosure are not necessarily limited thereto. According to an embodiment, the second insulation layer L2 may include an organic material.

The second insulation layer L2 may have a single-layer structure, or may include a plurality of layers according to an embodiment.

The second conductive layer CL2 may be disposed on (e.g., disposed directly thereon) the second insulation layer L2. At least a portion of the second conductive layer CL2 may be disposed in the upper contact hole CH_U.

The second conductive layer CL2 may be electrically connected to a portion of the second bridge layer BR2 exposed by the upper contact hole CH_U.

The second conductive layer CL2 and the second bridge layer BR2 may be connected to each other in the second contact area CA2. For example, the second conductive layer CL2 and the second bridge layer BR2 may directly contact each other in the second contact area CA2.

The second conductive layer CL2 may include various conductive materials. For example, the second conductive layer CL2 may include a metallic material. For example, in an embodiment the second conductive layer CL2 may include one or more compounds selected from gold (Au), silver (Ag), tantalum (Ta), aluminum (Al), molybdenum (Mo), chromium (Cr), titanium (Ti), nickel (Ni), neodymium (Nd), copper (Cu), and platinum (Pt). However, embodiments of the present disclosure are not necessarily limited thereto.

The lower contact hole CH_B may have a first diameter D1. The upper contact hole CH_U may have a second diameter D2. The intermediate contact hole CH_M may have a third diameter D3. The first diameter D1, the second diameter D2, and the third diameter D3 may be defined based on a direction in which the plane where the base layer BSL (or the contact base BS_C) is disposed extends. The first diameter D1, the second diameter D2, and the third diameter D3 may be a maximum diameter of the lower contact hole CH_B, the upper contact hole CH_U and the intermediate contact hole CH_M, respectively. For example, in an embodiment the first diameter D1, the second diameter D2, and the third diameter D3 may be diameters of upper surfaces of the lower contact hole CH_B, the upper contact hole CH_U and the intermediate contact hole CH_M, respectively. However, embodiments of the present disclosure are not necessarily limited thereto.

According to an embodiment, the third diameter D3 may be greater than the first diameter D1. In this embodiment, the second bridge layer BR2 may be electrically connected to the first bridge layer BR1 with stability.

According to an embodiment, the third diameter D3 may be greater than the second diameter D2. In this embodiment, the second conductive layer CL2 may be electrically connected to the second bridge layer BR2 with stability.

According to an embodiment, the first diameter D1 may be greater than the second diameter D2. In this embodiment, a structure in which the second bridge layer BR2 and the second conductive layer CL2 are stacked on the first bridge layer BR1 may be stably formed.

According to an embodiment, the lower contact hole lower contact hole CH_B, the intermediate contact hole CH_M, and the upper contact hole CH_U may overlap each other, in a plan view. According to an embodiment, the first contact area CA1 and the second contact area CA2 may overlap each other in a plan view (e.g., in the thickness direction of the base layer BSL, or in the third direction DR3).

Hence, the first conductive layer CL1 and the second conductive layer CL2 spaced apart in the thickness direction (e.g., in the third direction DR3) of the base layer BSL and arranging two or more layers therebetween may be electrically connected to each other in the contact structure CS. According to an embodiment, since two or more layers are disposed between the first conductive layer CL1 and the second conductive layer CL2, the first conductive layer CL1 and the second conductive layer CL2 may be relatively spaced apart from each other (e.g., in the third direction DR3). According to an embodiment, the electrical connection structure between the first conductive layer CL1 and the second conductive layer CL2 which are relatively spaced from each other may be stably defined.

For example, the lower contact hole CH_B of the first insulation layer L1 is filled by the buffer insulation layer BUF, the inorganic insulation layer IOL and the first bridge layer BR, the second bridge layer BR2 is disposed on the buffer insulation layer BUF, and thus a risk of disconnection of the electrical connection structure due to steps formed by the various layers may be reduced.

In addition, according to an embodiment, since the lower contact hole CH_B and the upper contact hole CH_U overlap each other (e.g., in a plan view), the conductive parts extending along the thickness direction of the base layer BSL may be formed to overlap each other (e.g., in a plan view). In this embodiment, the parts electrically interconnecting the first conductive layer CL1 and the second conductive layer CL2 may reduce the area required on the plane.

Hence, the pixel circuit PXC and the wiring electrically connected thereto within a relatively narrow area in the display area DA may be efficiently formed. As a result, since the pixel circuit PXC and the wiring thereof may be disposed in the relatively narrow area, a resolution of the display device DD may be increased, and the display device DD with excellent display quality may be provided.

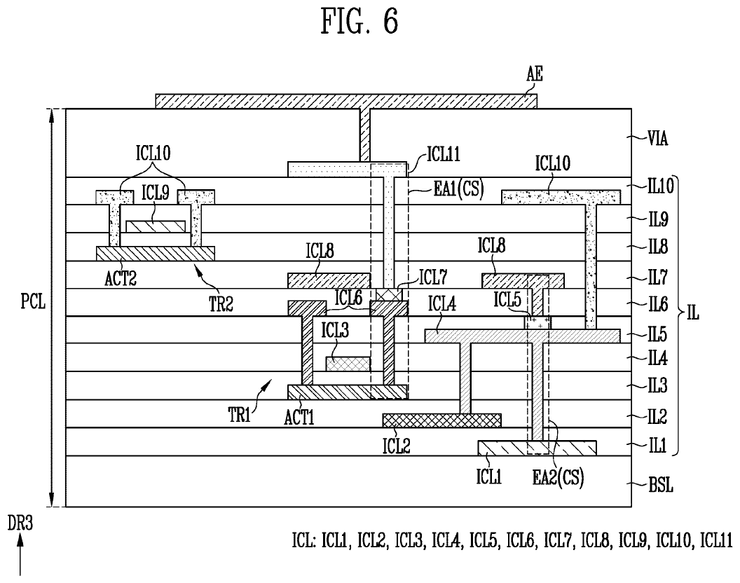

Hereinafter, referring to FIGS. 6-8, an embodiment of a display device DD including a contact structure CS is described. Descriptions overlapping with those described above will be explained in brief, or will not be repeated for economy of explanation.

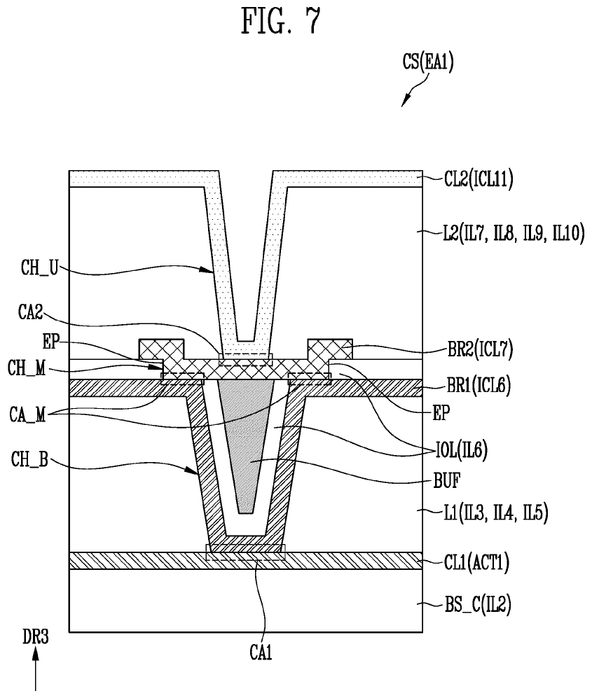

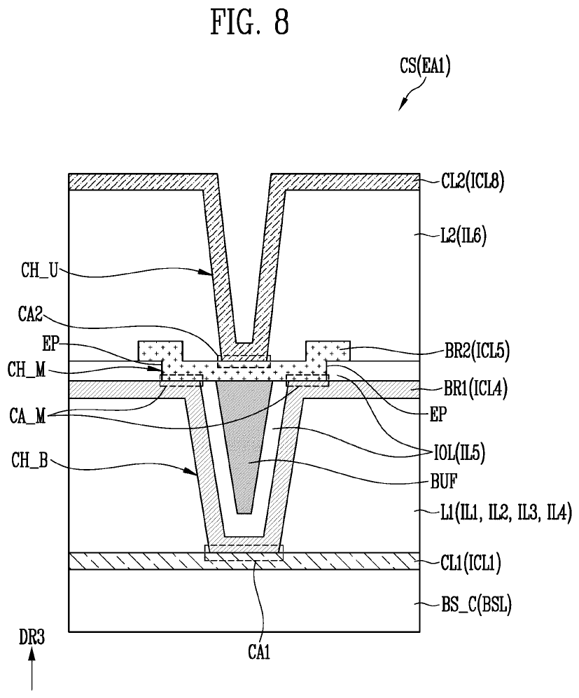

FIG. 6 is a schematic cross-sectional diagram illustrating a pixel circuit layer according to an embodiment. FIG. 7 is a schematic enlarged view of an area EA1 of FIG. 6. FIG. 8 is a schematic enlarged view of an area EA2 of FIG. 6.

According to an embodiment, the pixel circuit layer PCL may include a base layer BSL and an interlayer insulation layer IL, an interlayer conductive layer ICL, and active layers ACT1 and ACT2 formed on the base layer BSL. According to embodiment, FIG. 6 illustrates a structure in which the pixel circuit layer PCL includes first and second transistors TR1 and TR2. According to an embodiment, the pixel circuit layer PCL may include a via layer VIA for covering the interlayer conductive layer ICL (e.g., an eleventh interlayer conductive layer ICL11) disposed uppermost among the layers of the interlayer conductive layer ICL. According to an embodiment, a portion of the interlayer conductive layer ICL electrically connected to the pixel circuit PXC and the anode electrode AE may be electrically connected through a contact member formed in the via layer VIA.

According to an embodiment, at least portions of the interlayer insulation layers IL, the interlayer conductive layers ICL, and/or the active layers ACT1 and ACT2 may form the contact structure CS.

The interlayer insulation layer IL may be disposed on the base layer BSL, and may be disposed between the interlayer conductive layers ICL spaced apart in the third direction DR3 or between the interlayer conductive layer ICL and the active layers ACT1 and ACT2. According to an embodiment, the interlayer insulation layer IL may include a plurality of layers. For example, in an embodiment the interlayer insulation layer IL may include first through tenth interlayer insulation layers IL1 to IL10. However, embodiments of the present disclosure are not necessarily limited thereto.

The interlayer insulation layer IL may include various insulation materials. For example, the interlayer insulation layer IL may include an inorganic material. According to an embodiment, the interlayer insulation layer IL may include one or more compounds selected from silicon nitride (SiNx), silicon oxide (SiOx), silicon oxide (SiOxNy), and aluminum oxide (AlxOy). However, embodiments of the present disclosure are not necessarily limited thereto. According to an embodiment, the interlayer insulation layer IL may include an organic material.

The interlayer conductive layer ICL may be disposed on the base layer BSL, and may be disposed between interlayer insulation layers IL spaced apart in the third direction DR3. According to an embodiment, the interlayer conductive layer ICL may include a plurality of layers. For example, in an embodiment the interlayer conductive layer ICL may include first through eleventh interlayer conductive layers ICL1 to ICL11. However, embodiments of the present disclosure are not necessarily limited thereto.

The interlayer conductive layer ICL may include various conductive materials. For example, in an embodiment the interlayer conductive layer ICL may include one or more compounds selected from gold (Au), silver (Ag), tantalum (Ta), aluminum (Al), molybdenum (Mo), chromium (Cr), titanium (Ti), nickel (Ni), neodymium (Nd), copper (Cu), and platinum (Pt). However, embodiments of the present disclosure are not necessarily limited thereto.

The active layers ACT1 and ACT2 may be disposed on the interlayer insulation layer IL in some area. The active layers ACT1 and ACT2 may include the first active layer ACT1 and the second active layer ACT2. According to an embodiment, the first active layer ACT1 and the second active layer ACT2 may include different semiconductor materials from each other. For example, in an embodiment the first active layer ACT1 may include a polysilicon semiconductor material, and the second active layer ACT2 may include an oxide semiconductor material. However, embodiments of the present disclosure are not necessarily limited thereto.

According to an embodiment, the first transistor TR1 may include the first active layer ACT1, a gate electrode formed by the third interlayer conductive layer ICL3, and source/drain electrodes formed by the sixth interlayer insulation layer ICL6.

According to an embodiment, the second transistor TR2 may be disposed higher (e.g., in the third direction DR3) than the first transistor TR1, and may include the second active layer ACT2, a gate electrode formed by the ninth interlayer conductive layer ICL9, and source/drain electrodes formed by the tenth interlayer conductive layer ICL10. The second transistor TR2 may be spaced further from the base layer BSL than the first transistor TR1 (e.g., in the third direction DR3).

According to an embodiment, the pixel circuit layer PCL may include the transistors TR1 and TR2 including the active layers ACT1 and ACT2 including different semiconductor materials respectively, and accordingly, semiconductor materials may be suitably applied for each function of the transistors which form the pixel circuit PXC. In this embodiment, since the first and second transistors TR1 and TR2 may be formed at different heights with respect to the base layer BSL, a plurality of layers may be interposed between the active layers ACT1 and ACT2 and the interlayer conductive layers ICL. In this embodiment, the contact structure CS according to an embodiment may be applied to closely form the electrical connection structure between the layers.

According to an embodiment, FIG. 6 illustrates two examples of the contact structure CS.

Referring to FIG. 6 and FIG. 7, the eleventh interlayer conductive layer ICL11 and the first active layer ACT1 disposed adjacent to the via layer VIA may be electrically connected to each other based on the contact structure CS.

For example, in an embodiment the contact base BS_C may be formed by the second interlayer insulation layer IL2. The first conductive layer CL1 may be formed by the first active layer ACT1. The first insulation layer L1 may be formed by the third interlayer insulation layer IL3, the fourth interlayer insulation layer IL4, and the fifth interlayer insulation layer IL5. The first bridge layer BR1 may be formed by the sixth interlayer conductive layer ICL6. The inorganic insulation layer IOL may be formed by the sixth interlayer insulation layer IL6. The second bridge layer BR2 may be formed by the seventh interlayer conductive layer ICL7. The second insulation layer L2 may be formed by the seventh interlayer insulation layer IL7, the eighth interlayer insulation layer IL8, the ninth interlayer insulation layer IL9, and the tenth interlayer insulation layer IL10. The second conductive layer CL2 may be formed by the eleventh interlayer conductive layer ICL11.

Referring to FIGS. 6 and 8, the eighth interlayer conductive layer ICL8 and the first interlayer conductive layer ICL1 may be electrically connected to each other due to the contact structure CS.

For example, in an embodiment the contact base BS_C may be formed by the base layer BSL. The first conductive layer CL1 may be formed by the first interlayer conductive layer ICL1. The first insulation layer L1 may be formed by the first interlayer insulation layer IL1, the second interlayer insulation layer IL2, the third interlayer insulation layer IL3, and the fourth interlayer insulation layer IL4. The first bridge layer BR1 may be formed by the fourth interlayer conductive layer ICL4. The inorganic insulation layer IOL may be formed by the fifth interlayer insulation layer IL5. The second bridge layer BR2 may be formed by the fifth interlayer conductive layer ICL5. The second insulation layer L2 may be formed by the sixth interlayer insulation layer IL6. The second conductive layer CL2 may be formed by the eighth interlayer conductive layer ICL8.

However, embodiments of the present disclosure are not necessarily limited thereto and the contact structure CS may vary from the embodiment described above. The contact structure CS according to an embodiment may electrically connect various two layers spaced apart in the pixel circuit layer PCL.

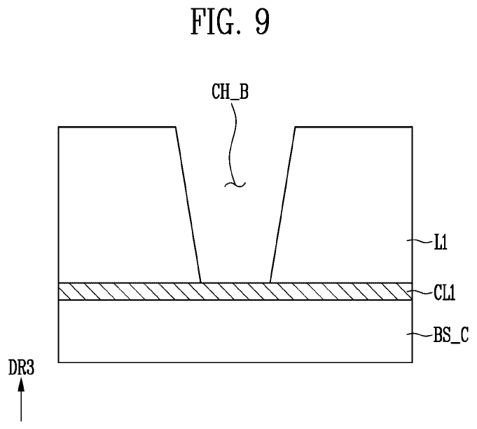

Referring to FIGS. 9 to 16, a method of manufacturing a contact structure CS according to an embodiment is described. Descriptions overlapping with those described above will be explained in brief, or will not be repeated for economy of explanation.

FIGS. 9 to 16 are schematic cross-sectional diagrams of process stages illustrating the method of manufacturing the contact structure according to an embodiment. For ease of explanation, FIGS. 9 to 16 illustrate the cross-sectional diagrams based on the cross-sectional structure aforementioned with reference to FIG. 5.

Referring to FIG. 9, in an embodiment the contact base contact base BS_C may be provided (e.g., prepared), the first conductive layer CL1 may be disposed (e.g., formed directly thereon) on the contact base contact base BS_C, and the first insulation layer L1 may be formed on the first conductive layer CL1 and patterned.

According to an embodiment, the conductive layer or the insulation layer on the contact base BS_C may be formed based on a conventional process for manufacturing a semiconductor device. For example, in an embodiment the conductive layer or the insulation layer on the contact base BS_C may be formed by a photolithography process, etched by various methods (e.g., wet etching, dry etching, etc.), and deposited by various methods (e.g., sputtering, chemical vapor deposition, etc.). However, embodiments of the present disclosure are not necessarily limited to a specific example.

In an embodiment, the first insulation layer L1 may then be patterned to expose a portion of the first conductive layer CL1, such as a portion of an upper surface of the first conductive layer CL1D. Hence, the first conductive layer CL1 may be exposed by the lower contact hole CH_B.

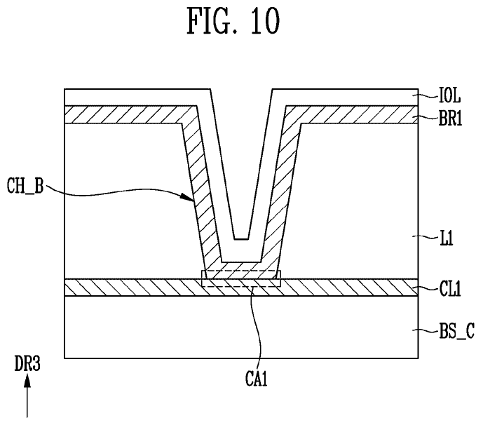

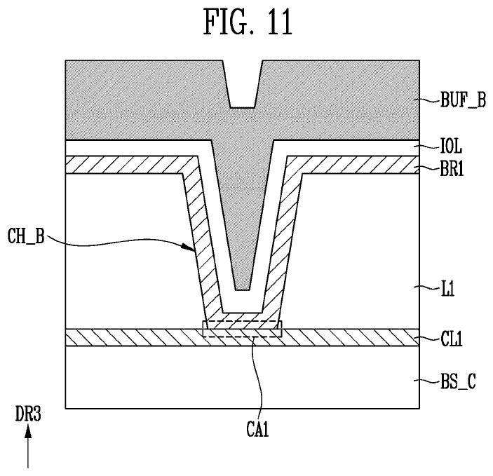

Referring to FIG. 10, the first bridge layer BR1 may be formed to cover the first insulation layer L1, and the inorganic insulation layer IOL may be disposed (e.g., formed directly thereon) on the first bridge layer BR1.

At this stage, at least a portion of the first bridge layer BR1 may be provided within the lower contact hole CH_B, and may be electrically connected to the first conductive layer CL1 through the first contact area CA1.

At this stage, at least a portion of the inorganic insulation layer IOL may be provided within the lower contact hole CH_B.

Referring to FIG. 11, the base buffer insulation layer BUF_B may be disposed (e.g., formed directly thereon) on the inorganic insulation layer IOL.

According to an embodiment, the base buffer insulation layer BUF_B may be a layer formed in which a flattening process (e.g., the CMP process) is performed thereon. In an embodiment, the base buffer insulation layer BUF_B may be formed to have a relatively large thickness. At least a portion of the base buffer insulation layer BUF_B may be provided in the lower contact hole CH_B.

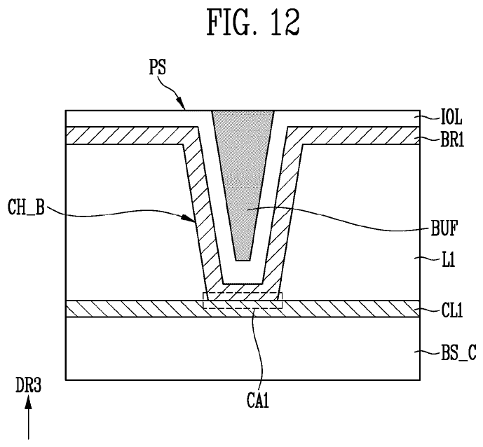

Referring to FIG. 12, the flattening process may be performed, and a portion of the base buffer insulation layer BUF_B may be removed to provide the buffer insulation layer BUF. For example, in an embodiment, the flattening process may include removing the base buffer insulation layer BUF_B until an upper surface of the inorganic insulation layer IOL is exposed.

At this stage, a portion of the base buffer insulation layer BUF_B provided in the lower contact hole CH_B may not be removed.

According to an embodiment, since the base buffer insulation layer BUF_B and the inorganic insulation layer IOL may include different materials from each other, the base buffer insulation layer BUF_B may be removed until the upper surface of the inorganic insulation layer IOL is exposed.

At this stage, the inorganic insulation layer IOL and the buffer insulation layer BUF may form an upper planar surface PS which is substantially flat.

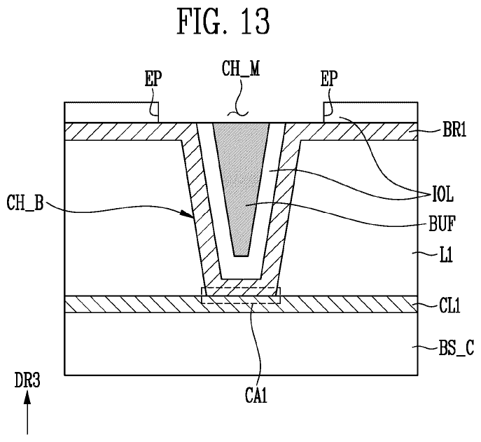

Referring to FIG. 13, at least a portion of the inorganic insulation layer IOL may be removed, and a portion of the first bridge layer BR1 may be exposed. For example, a portion of the upper surface of the first bridge layer BR1 may be exposed.

At this stage, the intermediate contact hole CH_M may be formed by the removal of the portion of the inorganic insulation layer IOL, and the first bridge layer BR1, the inorganic insulation layer IOL and the buffer insulation layer BUF may be exposed. In addition, as the intermediate contact hole CH_M is formed, the end part EP of the inorganic insulation layer IOL may be formed. In an embodiment, an upper surface of the buffer insulation layer BUF, an upper surface of the portion of the inorganic insulation layer IOL in the lower contact hole CH_B and the upper surface of the first bridge layer BR1 exposed by the inorganic insulation layer IOL may form a substantially planar (e.g., a substantially flat) surface.

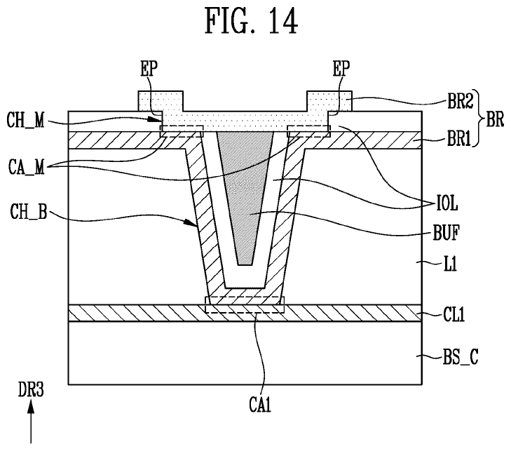

Referring to FIG. 14, in an embodiment the second bridge layer BR2 may be formed to cover the inorganic insulation layer IOL, the first bridge layer BR1, and the buffer insulation layer BUF. For example, the second bridge layer BR2 may be formed on the substantially flat upper surface of the buffer insulation layer BUF, upper surface of the portion of the inorganic insulation layer IOL in the lower contact hole CH_B and the upper surface of the first bridge layer BR1 exposed by the intermediate contact hole CH_M. The substantially flat upper surface of the exposed portion of the first bridge layer BR1 may provide increased contact between the first bridge layer BR1 and the second bridge layer BR2 in the intermediate contact area CA_M.

At this stage, at least a portion of the second bridge layer BR2 may be provided in the intermediate contact hole CH_M, and may be electrically connected to the first bridge layer BR1 through the intermediate contact area CA_M.

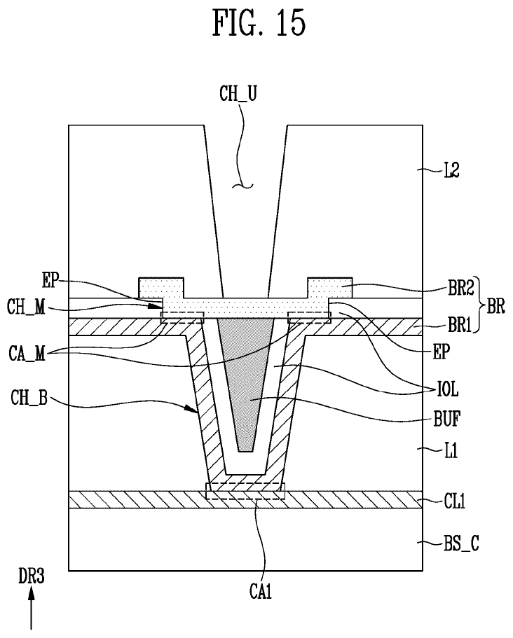

Referring to FIG. 15, the second insulation layer L2 may be disposed on (e.g., formed directly thereon) the inorganic insulation layer IOL and the second bridge layer BR2 and may then be patterned.

At this stage, the second insulation layer L2 may be patterned to expose a portion of the second bridge layer BR2. For example, in an embodiment the second insulation layer L2 may be patterned to expose a central portion of an upper surface of the second bridge layer BR2. Hence, the second bridge layer BR2 may be exposed by the upper contact hole CH_U.

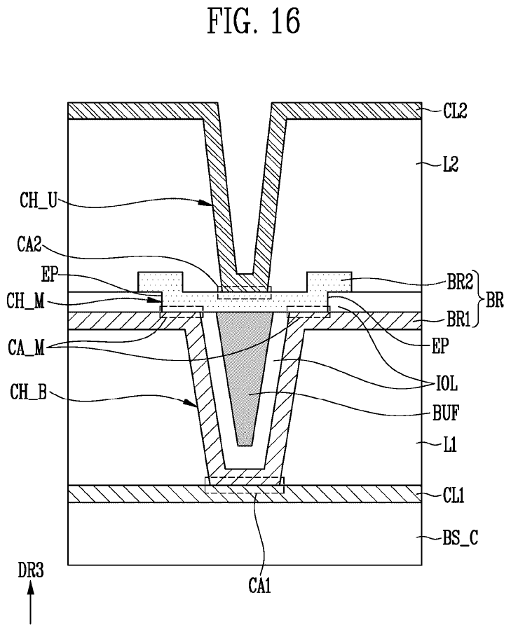

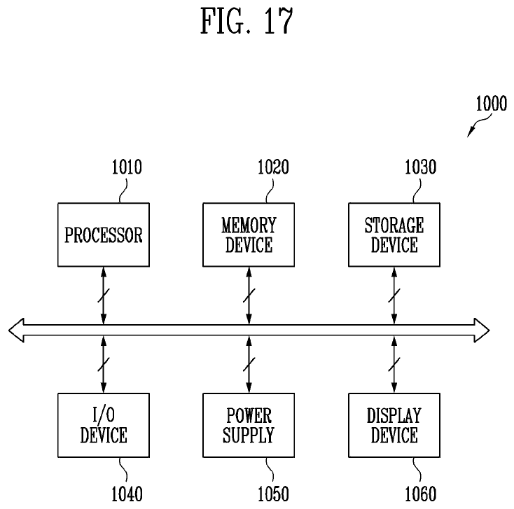

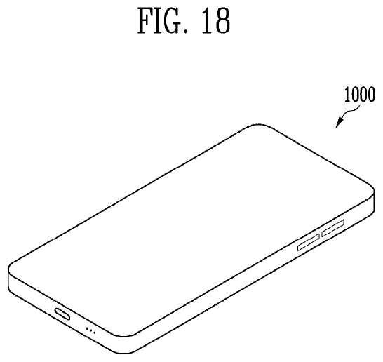

Referring to FIG. 16, the second conductive layer CL2 may be formed to cover the second insulation layer L2.

At this stage, at least a portion of the second conductive layer CL2 may be provided within the upper contact hole CH_U, and may be electrically connected to the second bridge layer BR2 through the second contact area CA2.

Thus, the first conductive layer CL1 and the second conductive layer CL2 spaced apart along the third direction DR3 may be adequately electrically interconnected in a relatively narrow area.

Hereinafter, an electronic device 1000 including the display device DD in accordance with an embodiment will be described.

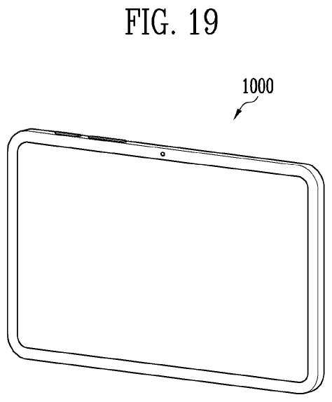

FIG. 19 is a schematic block diagram illustrating an electronic device 1000 including a display device in accordance with an embodiment. FIG. 20 is a schematic diagram illustrating an example where the electronic device 1000 of FIG. 19 is implemented as a smartphone. FIG. 21 is a schematic diagram illustrating an example where the electronic device 1000 of FIG. 19 is implemented as a tablet computer.

Referring to FIGS. 19 to 21, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 20, the electronic device 1000 may be implemented as a smartphone. In an embodiment, as illustrated in FIG. 21, the electronic device 1000 may be implemented as a tablet computer. However, the aforementioned examples are illustrative, and the electronic device 1000 is not necessarily limited to the aforementioned examples. For example, the electronic device 1000 may be implemented as a cellular phone, a video phone, a smartpad, a smartwatch, a navigation device for vehicles, a computer monitor, a laptop computer, a head-mounted display device, or the like.

The processor 1010 may perform specific calculations or tasks. In an embodiment, the processor 1010 may be a micro-processor, a central processing unit, an application processor, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be included in the I/O device 1040.

The power supply 1050 may supply power needed to perform the operation of the electronic device 1000. For example, the power supply 1050 may be a power management integrated circuit (PMIC). In an embodiment, the power supply 1050 may supply power to the display device 1060.

The display device 1060 may display an image corresponding to visual information of the electronic device 1000. The display device 1060 may be connected to other components through the buses or other communication links.

As set forth above, although the present disclosure has been explained with reference to non-limiting embodiments thereof, a person skilled in the art or a person with ordinary skill in the field of the technology will be able to understand that embodiments of the present disclosure may be modified and changed in various ways within the spirit and scope of the present disclosure.

Therefore, the technical scope of the present disclosure should not be limited to the described embodiments in the detailed description of the specification.

What is claimed is:

1. A display device comprising:
a pixel circuit layer comprising a contact structure that includes a first conductive layer, a first bridge layer electrically connected to the first conductive layer, a second bridge layer electrically connected to the first bridge layer, and a second conductive layer electrically connected to the second bridge layer; and
a light-emitting element disposed on the pixel circuit layer,
wherein the first conductive layer and the first bridge layer are connected to each other in a first contact area, and the second conductive layer and the second bridge layer are connected to each other in a second contact area, and
the first contact area and the second contact area overlap each other, in a plan view.

2. The display device according to claim 1, wherein:
the pixel circuit layer comprises a pixel circuit electrically connected to the light-emitting element and wiring electrically connected to the pixel circuit;
the contact structure comprises an electrical path in the pixel circuit or the wiring;
the first conductive layer comprises one of a metal material and a semiconductor material; and
the second conductive layer comprises a metallic material.

3. The display device according to claim 1, wherein the contact structure further comprises:
a first insulation layer disposed on the first conductive layer, and comprising a lower contact hole exposing the first conductive layer;
an inorganic insulation layer disposed on the first bridge layer, and comprising an intermediate contact hole exposing the first bridge layer; and
a second insulation layer disposed on the inorganic insulation layer and the second bridge layer, and comprising an upper contact hole exposing the second bridge layer.

4. The display device according to claim 3, wherein the lower contact hole, the intermediate contact hole, and the upper contact hole overlap each other, in the plan view.

5. The display device according to claim 3, wherein:
a portion of the inorganic insulation layer is disposed within the lower contact hole; and
the contact structure further comprises a buffer insulation layer disposed in the lower contact hole and covering the portion of the inorganic insulation layer within the lower contact hole.

6. The display device according to claim 5, wherein the buffer insulation layer and the inorganic insulation layer comprise different materials from each other.

7. The display device according to claim 5, wherein the buffer insulation layer has a flat upper surface, and does not cover a portion of the first bridge layer exposed by the intermediate contact hole.

8. The display device according to claim 5, wherein:
the inorganic insulation layer faces the intermediate contact hole and comprises an end part covered by the second bridge layer; and
the second bridge layer is disposed in an area greater than or equal to the lower contact hole and entirely covers the lower contact hole, in the plan view.

9. The display device according to claim 3, wherein the intermediate contact hole has a greater diameter than the lower contact hole.

10. The display device according to claim 3, wherein the intermediate contact hole has a greater diameter than the upper contact hole.

11. The display device according to claim 3, wherein the lower contact hole has a greater diameter than the upper contact hole.

12. The display device according to claim 1, wherein:
the pixel circuit layer comprises a base layer, a first transistor disposed on the base layer and comprising a first active layer, and a second transistor disposed on the base layer and comprising a second active layer;
the second transistor is spaced further away from the base layer than the first transistor; and
the first active layer and the second active layer comprise different semiconductor materials from each other.

13. The display device according to claim 12, wherein:
the first active layer comprises a polysilicon semiconductor material; and
the second active layer comprises an oxide semiconductor material.

14. A display device comprising:
a pixel circuit layer comprising a contact structure; and
a light-emitting element disposed on the pixel circuit layer,
wherein the contact structure comprises:
a first conductive layer;
an insulation layer disposed on the first conductive layer, and comprising a lower contact hole exposing a portion of the first conductive layer;
a bridge layer electrically connected to the portion of the first conductive layer exposed by the lower contact hole;
an inorganic insulation layer exposing a portion of the bridge layer, a portion of the inorganic insulation layer is disposed within the lower contact hole; and
a buffer insulation layer disposed in the lower contact hole, and
the inorganic insulation layer and the buffer insulation layer comprise different materials from each other.

15. A method of manufacturing a contact structure, the method comprising:
forming a first conductive layer on a contact base;
forming a first insulation layer on the first conductive layer and patterning the first insulation layer;
forming a first bridge layer electrically connected to the first conductive layer;
forming an inorganic insulation layer on the first bridge layer;
forming a buffer insulation layer on the inorganic insulation layer;
forming a second bridge layer on the first bridge layer, the inorganic insulation layer and the buffer insulation layer, the second bridge layer is electrically connected to the first bridge layer;
forming a second insulation layer on the second bridge layer and patterning the second insulation layer; and
forming a second conductive layer on the second insulation layer, the second conductive layer is electrically connected to the second bridge layer.

16. The method according to claim 15, wherein the forming of the buffer insulation layer comprises:
forming a base buffer insulation layer on the inorganic insulation layer; and
removing a portion of the base buffer insulation layer, and
the base buffer insulation layer and the inorganic insulation layer comprise different materials from each other.

17. The method according to claim 16, wherein the removing of the portion of the base buffer insulation layer comprises removing the base buffer insulation layer until an upper surface of the inorganic insulation layer is exposed, and
the removing of the portion of the base buffer insulation layer is performed by a chemical mechanical polishing (CMP) process.

18. The method according to claim 16, further comprising:
after the forming of the buffer insulation layer, exposing the first bridge layer by removing a portion of the inorganic insulation layer,
wherein the patterning of the first insulation layer comprises forming a lower contact hole exposing the first conductive layer,
the exposing of the first bridge layer comprises forming an intermediate contact hole exposing the first bridge layer, and
the patterning of the second insulation layer comprises forming an upper contact hole exposing the second bridge layer.

19. The method according to claim 18, wherein a portion of the inorganic insulation layer and the buffer insulation layer are disposed in the lower contact hole.

20. The method according to claim 19, wherein the forming of the second bridge layer comprises covering the first bridge layer and the portion of the inorganic insulation layer and the buffer insulation layer in the lower contact hole with the second bridge layer.

21. A display device comprising:
a pixel circuit layer comprising a contact structure; and
a light-emitting element disposed on the pixel circuit layer,
wherein the contact structure comprises:
a first conductive layer disposed on a contact base;
an insulation layer disposed on the first conductive layer, the insulation layer including a lower contact hole exposing a portion of the first conductive layer;
a first bridge layer disposed on the insulation layer, the first bridge layer including a first portion disposed above the insulation layer and a second portion extending within the lower contact hole and directly contacting the portion of the first conductive layer exposed by the lower contact hole in a first contact area;
an inorganic insulation layer disposed on the first and second portions of the first bridge layer, the inorganic insulation layer including an intermediate contact hole partially exposing the first portion of the first bridge layer, the first portion of the first bridge layer exposed by the intermediate contact hole having a substantially flat upper surface;
a buffer insulation layer disposed on the inorganic insulation layer in the lower contact hole;
a second bridge layer disposed in the intermediate contact hole and directly contacting the substantially flat upper surface of the first portion of the first bridge layer exposed by the intermediate contact hole in an intermediate contact area; and
a second conductive layer electrically connected to the second bridge layer in a second contact area.

22. The display device of claim 21, wherein the inorganic insulation layer and the buffer insulation layer are composed of materials having different etch rates from each other.

23. The display device of claim 21, wherein:
the buffer insulation layer includes silicon oxide and the inorganic insulation layer includes silicon nitride; or
the buffer insulation layer includes silicon nitride and the inorganic insulation layer includes silicon oxide.

24. An electronic device, comprising:
a processor configured to provide input image data;
a display device configured to display an image based on the input image data, the display device including sub-pixel areas; and
a power supply configured to supply power to the display device,
wherein:
the display device comprises:
a pixel circuit layer comprising a contact structure that includes a first conductive layer, a first bridge layer electrically connected to the first conductive layer, a second bridge layer electrically connected to the first bridge layer, and a second conductive layer electrically connected to the second bridge layer; and
a light-emitting element disposed on the pixel circuit layer,
the first conductive layer and the first bridge layer are directly connected to each other in a first contact area, and the second conductive layer and the second bridge layer are directly connected to each other in a second contact area, and
the first contact area and the second contact area overlap each other, in a plan view.
